(19) United States
(12) Patent Application Publication
(10) Pub. No.: US 2021/0151300 A1
(43) Pub. Date: May 20, 2021

(54) SUBSTRATE PROCESSING APPARATUS AND SEMICONDUCTOR DEVICE MANUFACTURING METHOD USING THE SAME

(71) Applicant: SAMSUNG ELECTRONICS CO., LTD., Suwon-si (KR)

(72) Inventors: Jieun JUNG, Hwaseong-si (KR); Siqing LU, Seongnam-si (KR); Soonam PARK, Seongnam-si (KR); Kyuhee HAN, Seongnam-si (KR)

(21) Appl. No.: 17/021,166

(22) Filed: Sep. 15, 2020

(30) Foreign Application Priority Data
Nov. 20, 2019 (KR) 10-2019-0149877

(51) Int. Cl. H01J 37/32

(52) U.S. Cl. CPC H01J 37/32724; H01J 2237/334; H01J 37/3244; H01J 37/32357

(57) ABSTRACT

A substrate processing apparatus and a method of manufacturing a semiconductor device, the apparatus including a plasma region in which plasma is generated; a processing region in which a substrate is processable; a shower head including a first channel and a second channel, the first channel being a passage through which the plasma flows between the plasma region and the processing region and the second channel being a passage through which a process gas is supplied to the processing region, the first channel and the second channel being separated from each other; a substrate support supporting the substrate in the processing region; and a cooler configured to supply a cooling fluid to a cooling channel of the substrate support.

### CROSS-REFERENCE TO RELATED APPLICATION

Korean Patent Application No. 10-2019-0149877, filed on Nov. 20, 2019, in the Korean Intellectual Property Office, and entitled: “Substrate Processing Apparatus and Semiconductor Device Manufacturing Method Using the Same.

### BACKGROUND

### 1. Field

Embodiments relate to a substrate processing apparatus and a method of manufacturing a semiconductor device using the same.

### 2. Description of the Related Art

Plasma may be widely used in a manufacturing process of a semiconductor device, a plasma display panel (PDP), a liquid crystal display (LCD), a solar cell, and the like. Processes in which plasma is used may include dry etching, dry cleaning, plasma enhanced chemical vapor deposition (PECVD), sputtering, ashing, and the like. Capacitively coupled plasma (CCP), inductively coupled plasma (ICP), a mixture of CCP and ICP, helicon plasma, microwave plasma, or the like may be used in a plasma process.

### SUMMARY

The embodiments may be realized by providing a substrate processing apparatus including a plasma region in which plasma is generated; a processing region in which a substrate is processable; a shower head including a first channel and a second channel, the first channel being a passage through which the plasma flows between the plasma region and the processing region and the second channel being a passage through which a process gas is supplied to the processing region, the first channel and the second channel being separated from each other; a substrate support supporting the substrate in the processing region; and a cooler configured to supply a cooling fluid to a cooling channel of the substrate support.

The embodiments may be realized by providing a substrate processing apparatus including a plasma region to which plasma generated from a first process gas is supplied; a processing region in which the plasma supplied from the plasma region and a second process gas are mixed to generate an etchant for processing a substrate; a substrate support on which the substrate is supportable in the processing region; and a cooler configured to supply a cooling fluid to a cooling channel of the substrate support, wherein the cooler includes a refrigerant cycle through which a refrigerant circulates; a cooling fluid cycle through which the cooling fluid circulates; and a heat exchanger configured to perform heat exchange between the refrigerant and the cooling fluid.

The embodiments may be realized by providing a substrate processing apparatus including a process chamber including a plasma region, a processing region, a shower head separating the plasma region from the processing region, and a substrate support on which a substrate is supportable in the processing region; a remote plasma supply configured to generate a plasma from a first process gas and to supply the plasma to the plasma region; a first gas supply configured to supply the first process gas to the remote plasma supply; a second gas supply configured to supply a second process gas to the shower head; and a cooler configured to cool the substrate support, the cooler including a refrigerant cycle through which a refrigerant circulates, a cooling fluid cycle through which a cooling fluid circulates, and a heat exchanger performing heat exchange between the refrigerant and the cooling fluid, wherein the shower head includes a first channel configured to supply the plasma in the plasma region to the processing region and a second channel configured to supply the second process gas to the processing region, and the first channel and the second channel are separated from each other, and radicals to be supplied to the processing region through the first channel and the second process gas supplied through the second channel are mixed to generate an etchant for cleaning the substrate.

The embodiments may be realized by providing a method of manufacturing a semiconductor device, the method including forming a hole in a substrate by removing a portion of the substrate; forming a sidewall protection layer that includes an object to be cleaned such that forming the sidewall protection layer includes cooling the substrate to a first temperature and reacting an etchant with the object to be cleaned on an inner wall of the hole at the first temperature; and exposing the inner wall of the hole by removing the sidewall protection layer, wherein the sidewall protection layer is non-volatile at the first temperature.

### BRIEF DESCRIPTION OF THE DRAWINGS

Features will be apparent to those of skill in the art by describing in detail exemplary embodiments with reference to the attached drawings in which:

FIG. 1 is a cross-sectional view schematically illustrating a substrate processing apparatus according to example embodiments;

FIG. 2 is an enlarged cross-sectional view of a region of FIG. 1 indicated by “II”;

FIG. 3 is a configuration diagram of a cooler according to example embodiments;

FIG. 4 is a cross-sectional view illustrating a substrate processing apparatus according to example embodiments;

FIG. 5 is a cross-sectional view illustrating a substrate processing apparatus according to example embodiments;

FIG. 6 is a flowchart of a substrate processing method according to example embodiments;

FIGS. 7A to 7F are cross-sectional views of stages in a substrate processing method according to example embodiments;

FIG. 8 is a cross-sectional view of a stage in a method of operating a substrate processing apparatus according to example embodiments; and

FIG. 9 is a flowchart of a method of manufacturing a semiconductor device according to example embodiments.

### DETAILED DESCRIPTION

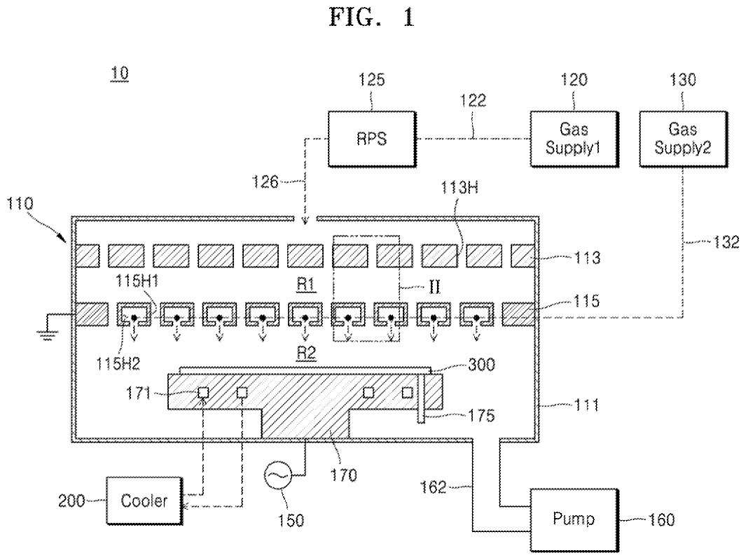

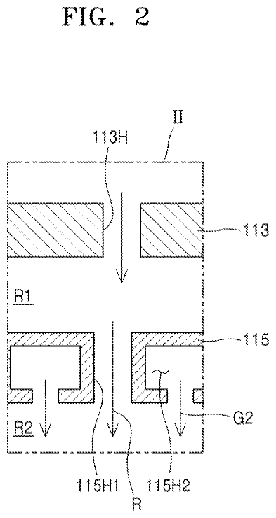

FIG. 1 is a cross-sectional view schematically illustrating a substrate processing apparatus 10 according to example embodiments. FIG. 2 is an enlarged cross-sectional view of a portion indicated by “II” of FIG. 1.

Referring to FIGS. 1 and 2, the substrate processing apparatus 10 may include a process chamber 110, a first gas supply 120, a second gas supply 130, a remote plasma supply 125, and a cooler 200.

The process chamber 110 may include the chamber for processing a substrate 300 by using plasma. In an implementation, the process chamber 110 may include the chamber for performing a semiconductor process such as deposition, etching, and cleaning on the substrate 300. Depending on the function of the process chamber 110, a name of the substrate processing apparatus 10 may be subdivided or different. The substrate processing apparatus 10 may be a deposition apparatus, an etching apparatus, or a cleaning apparatus, depending on processes performed in the process chamber 110, e.g., deposition, etching, and cleaning processes. In an implementation, the etching process and the cleaning process may be performed together in the process chamber 110.

Here, the “substrate” may refer to the substrate itself, or a laminated structure including the substrate and a predetermined layer or film formed on the surface thereof. In addition, a “surface of the substrate” may refer to an exposed surface of the substrate itself, or an exposed surface of the predetermined layer or film formed on the substrate, or the like. In an implementation, the substrate may include a wafer or may include the wafer and at least one material film on the wafer. The material film may include an insulating film and/or a conductive film formed on the wafer by various methods such as deposition and coating, plating. In an implementation, the insulating film may include an oxide film, a nitride film, an oxynitride film, or the like, and the conductive film may include a metal film, a polysilicon film, or the like. In an implementation, the material film may include a single film or multiple films formed on the wafer. In addition, the material film may be formed on the wafer with a predetermined pattern.

The process chamber 110 may include a chamber body 111, a first shower head 113, a second shower head 115, and a substrate support 170. The process chamber 110 may include a plasma region R1 in which plasma may be generated, or an externally generated plasma may be introduced, and a processing region R2 in which the substrate 300 is processed.

In an implementation, the chamber body 111 may define an interior space of the process chamber 110, and the interior space may be sealed from the outside. An overall outer structure of the chamber body 111 may have a cylindrical shape, an elliptical pillar shape, or a polygonal pillar shape, or the like. The chamber body 111 may include a metal material and may be maintained in an electrical ground state to block noise from the outside during the plasma process. A liner may be arranged inside the chamber body 111. The liner may help protect the chamber body 111 and may cover metal structures in the chamber body 111 to help prevent metal contamination (which could otherwise occur due to arcing inside the process chamber 110). In an implementation, the liner may include the metal such as aluminum or a ceramic, or the like. In an implementation, the liner may include a material film resistant to plasma at the plasma region R1. In an implementation, the material film resistant to plasma may include, e.g., an yttrium oxide (Y₂O₃) film.

The chamber body 111 may be connected to an exhaust pump 160 via a discharge pipe 162. By-products after the plasma process may be discharged through the discharge pipe 162 by using the exhaust pump 160. In addition, the exhaust pump 160 may perform a function of adjusting pressure in the process chamber 110.

The first shower head 113 may be mounted in the chamber body 111. The first shower head 113 may include a plurality of holes 113H through which gas may flow. The plasma to be supplied from the outside may be supplied to the plasma region R1 through the hole 113H of the first shower head 113.

The remote plasma supply 125 may be connected to the first gas supply 120 through a first gas supply line 122 and may generate the plasma by using a first process gas to be supplied from the first gas supply 120. The remote plasma supply 125 may supply the generated plasma to the process chamber 110 through a plasma supply line 126. In an implementation, the remote plasma supply 125 may generate the plasma by applying a power to the first process gas. The power may be applied as, e.g., a radio frequency (RF) power in the form of an electromagnetic wave with a predetermined frequency and intensity. In an implementation, the power may be applied in the form of a continuous wave or in the form of a pulse with an on-off period in the form of the electromagnetic wave.

The plasma may include various components such as radicals, ions, electrons, ultraviolet rays. At least one of the radicals, ions, electrons, ultraviolet rays, and the like may be used to process the substrate 300, e.g., in the etching, cleaning, or deposition process. The radicals may be electrically neutral, and the ions may be electrically polar. In an implementation, the radicals may be used to isotropically remove an object to be cleaned in the cleaning process using the plasma or to isotropically remove an etching object to be etched in the etching process using the plasma. In an implementation, the radicals may be used to prevent or inhibit the deposition of certain components in the deposition process. On the other hand, the ions may be used to anisotropically remove the object to be cleaned in the cleaning process or to anisotropically remove the etching object in the etching process.

The second shower head 115 may be arranged in the chamber body 111 and may be spaced downwardly apart from the first shower head 113 (e.g., in a direction toward the substrate support 170). The second shower head 115 may define the plasma region R1 together with the first shower head 113 (e.g., the plasma region R1 may be between the first shower head 113 and the second shower head 115). In an implementation, the second shower head 115 may be between the plasma region R1 and the processing region R2 to separate and distinguish the plasma region R1 from the processing region R2.

The second shower head 115 may have a flat plate shape, and may have a circular, elliptical, or polygonal shape in plan view. The second shower head 115 may include a material resistant to plasma or may include metal, ceramic, or the like. In an implementation, the material film resistant to plasma may be coated on a surface of the second shower head 115.

The second shower head 115 may supply the plasma of the plasma region R1 along with a second process gas G2 (to be supplied from the second gas supply 130), to the processing region R2 through separate passages. In an implementation, the second shower head 115 may include a first channel 115H1 (which is a passage through which the plasma of the plasma region R1 may be supplied to the processing region R2), and a second channel 115H2 (which is a passage through which the second process gas G2 to be supplied from the second gas supply 130 to the processing region R2). The second shower head 115 may be referred to as a dual-channel shower head in that it may include two channels separated from each other.

A plurality of first channels 115H1 may be in the second shower head 115, and the plurality of first channels 115H1 may vertically penetrate the second shower head 115, respectively. The plasma in the plasma region R1 may flow downwardly through the plurality of first channels 115H1 and may be supplied to the processing region R2. In an implementation, the plurality of first channels 115H1 may have the same size and may be spaced at equal intervals apart from each other. In an implementation, the plurality of first channels 115H1 may have different sizes. In an implementation, a density of the first channels 115H1 may vary according to positions thereof in the second shower head 115.

The second channel 115H2 may be a channel separated from the first channel 115H1. The second channel 115H2 may be connected to the second gas supply 130 through a second gas supply line 132. The second channel 115H2 may directly supply the second process gas G2 to be supplied from the second gas supply 130 to the processing region R2. In an implementation, the second process gas G2 may be introduced through a side of the second shower head 115 and may be evenly distributed to a whole surface of the second shower head 115 through the second channel 115H2. The second process gas G2 to be distributed through the second channel 115H2 may be supplied to the processing region R2 through a plurality of outlets of the second channel 115H2 which are exposed toward the processing region R2.

In an implementation, as illustrated in FIG. 1, the second shower head 115 may be subdivided into a plurality of square boxes in a cross-sectional view, as indicated by a dotted line, and the plurality of outlets may be connected to each other through an inner passage of the second channel 115H2 provided in the second shower head 115.

In an implementation, the second shower head 115 may be used to filter components of the plasma moving from the plasma region R1 to the processing region R2. In an implementation, in the cleaning process or the etching process using plasma, the radicals R (which are electrically neutral) may be supplied to the processing region R2 through the first channel 115H1 of the second shower head 115, and the ions may not pass through the second shower head 115. In an implementation, the second shower head 115 may function to reduce or substantially remove the ions moving from the plasma region R1 to the processing region R2. Such a filtering function of the second shower head 115 may be achieved by the geometry of the first channel 115H1, e.g., the aspect ratio, or the taper shape, or the like of the first channel 115H1. In an implementation, a bias power may be applied to the second shower head 115 to block the flow of ions. In an implementation, the second shower head 115 may be electrically ground state.

In an implementation, the first process gas may include at least one cleaning source gas or at least one etching source gas. In an implementation, the first process gas may include a source gas containing fluorine. In an implementation, the first process gas may include fluorine (F₂), bromine trifluoride (BrF₃), chlorine trifluoride (ClF₃), nitrogen trifluoride (NF₃), hydrofluoric acid (HF), sulfur hexafluoride (SF₆), or xenon difluoride (XeF₂), or may include a fluorocarbon (CxFy) gas such as tetrafluoromethane (CF₄), hexafluoroethane (C₂F₆), octafluoropropane (C₃F₈), or octafluorocyclobutane (C₄F₈). In an implementation, the first process gas may be appropriately selected depending on the object to be cleaned or etched. In an implementation, the first process gas may include a source gas containing a chlorine element (Cl), e.g., chlorine (Cl₂), boron trichloride (BCl₃), carbon tetrachloride (CCl₄), or silicon tetrachloride (SiCl₄), or may include an oxygen element (O), e.g., oxygen (O₂) or ozone (O₃).

In an implementation, the second process gas G2 may be a source gas for generating an etchant that is used to remove the object to be cleaned or etched, by reacting with the radicals R to be supplied to the processing region R2 through the first channel 115H1 of the second shower head 115. In an implementation, the second process gas G2 may include the source gas containing hydrogen, e.g., methane (CH₄), ammonia (NH₃), or hydrazine (N₂H₄).

Plasma components of the plasma region R1 may be filtered while passing through the second shower head 115, and a ratio of ions/radicals to be supplied to the processing region R2 may be adjusted by using the second shower head 115. By appropriately adjusting the ratio of ions/radicals by using the second shower head 115, the cleaning process or the etching process may be performed with desired characteristics.

In an implementation, the first process gas may be made into a highly reactive plasma state and then may be mixed with the second process gas G2 to generate the etchant. The second process gas G2 may be supplied to the processing region R2 through a separate channel in the second shower head 115, and the second process gas G2 may maintain natural characteristics without dissociating and may be mixed with the radicals that pass through the shower head 115, thereby generating the etchant.

The substrate support 170 may be arranged under (e.g., facing) the processing region R2 of the process chamber 110. The substrate support 170 may support the substrate 300, which may be the object to be processed in the plasma process.

In an implementation, the substrate support 170 may include an electrostatic chuck configured to support the substrate 300 with electrostatic force and a chuck support for supporting the electrostatic chuck. The electrostatic chuck may include an electrode therein for chucking and dechucking the substrate 300. The chuck support may support the electrostatic chuck arranged thereon, and may include metal such as aluminum, or a ceramic insulator such as alumina. A heating device such as a heater may be arranged inside the chuck support, and heat from the heater may be transferred to the electrostatic chuck or the substrate 300. In an implementation, a wire for the application of power may be arranged in the chuck support, in which the wire may be connected to the electrode in the electrostatic chuck. In an implementation, the substrate support 170 may include a vacuum chuck configured to support the substrate 300 by using a vacuum, or the substrate support 170 may be configured to mechanically support the substrate 300.

The substrate support 170 may include a lift pin 175 configured to lift up the substrate 300 from a surface of the substrate support 170 on which the substrate 300 is seated. The lift pin 175 may be accommodated in a hole in the substrate support 170 and may be installed to be movable in a vertical direction in the substrate support 170. The lift pin 175 may move in the vertical direction to raise and lower the substrate 300. The substrate support 170 may include a number of lift pins 175 suitable for supporting the substrate 300. In an implementation, the substrate support 170 may include three or more lift pins 175 evenly spaced apart from each other in a circumferential direction of the substrate support 170.

When the substrate 300 to be processed is introduced into the process chamber 110 or the substrate 300 is taken out of the process chamber 110, the lift pin 175 may be in a pin-up state projecting upwardly from the substrate support 170 to support the substrate 300. In an implementation, as the substrate 300 is being processed in the process chamber 110, the lift pin 175 may be in a pin-down state lowered below a top surface of the substrate support 170, thereby placing the substrate 300 on the substrate support 170.

An RF bias source 150 may be connected to the substrate support 170. The RF bias source 150 may be configured to apply the RF power to the substrate support 170. In an implementation, the RF bias source 150 may apply a low frequency RF power of less than about 200 kHz to the substrate support 170 during the cleaning or etching process for the substrate 300. In an implementation, the RF bias source 150 may remove the RF power to be supplied to the substrate support 170 during the cleaning or etching process for the substrate 300.

The cooler 200 may be configured to cool the substrate support 170. The cooler 200 may supply a cooling fluid into a cooling channel 171 of the substrate support 170. The cooling channel 171 of the substrate support 170 is a passage through which the cooling fluid may flow and may have a concentric or helical pipe shape around a central axis of the substrate support 170. The cooler 200 may adjust a temperature of the substrate support 170 and the temperature of the substrate 300 mounted on the substrate support 170, by adjusting the temperature, flux, and flow rate of the cooling fluid to be supplied to the cooling channel 171 of the substrate support 170.

The cooling fluid may include a material that may be operable over a wide temperature range. In an implementation, the cooling fluid may include water, ethylene glycol, silicone oil, liquid teflon, or mixtures thereof. The cooler 200 may adjust the temperature of the cooling fluid to a range of a cryogenic temperature. In an implementation, the cooler 200 may adjust the temperature of the cooling fluid to the cryogenic temperature and may also adjust the temperature of the cooling fluid to room temperature.

The cooler 200 may be configured to adjust and maintain the substrate 300 mounted on the substrate support 170 to the cryogenic temperature during the plasma process. In an implementation, the cooler 200 may cool the substrate 300 to a predetermined temperature, e.g., −130° C. to −30° C. By performing the plasma process, e.g., the cleaning process or the etching process, on the substrate 300, in such a cryogenic environment, damages of the substrate 300 due to plasma may be reduced.

In an implementation, the substrate processing apparatus 10 may include a controller for controlling the substrate processing process using the substrate processing apparatus 10.

The controller may include a computing device such as a workstation computer, a desktop computer, a laptop computer, a tablet computer. The controller may include a processor, a microprocessor, a central processing unit (CPU), or a firmware. The controller may be implemented by, e.g., a general-purpose computer or specific hardware such as a digital signal process (DSP), a field programmable gate array (FPGA) and an application specific integrated circuit (ASIC).

An operation of the controller may be implemented with instructions stored on a machine readable medium that may be read and executed by one or more processors. Here, the machine readable medium may include a suitable mechanism for storing and/or transmitting information in the form readable by a machine (e.g., the computing device). In an implementation, the machine readable medium may include read only memory (ROM), random access memory (RAM), magnetic disk storage media, optical storage media, flash memory devices.

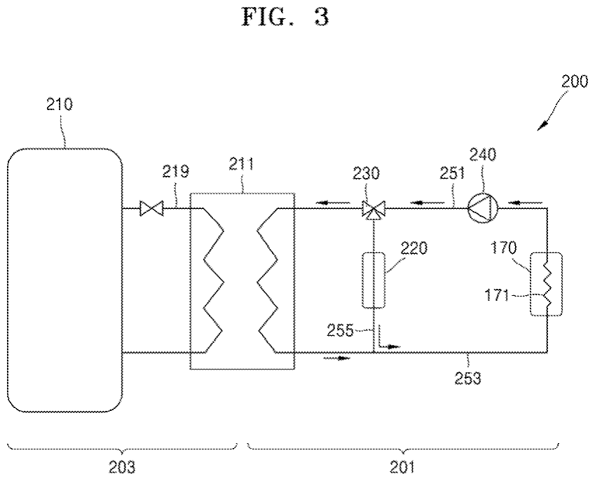

FIG. 3 is a configuration diagram of a cooler 200 according to example embodiments.

Referring to FIG. 3 together with FIG. 1, the cooler 200 may include a cooling fluid cycle 201 (through which the cooling fluid circulates) and a refrigerant cycle 203 (through which a refrigerant circulates). The cooling fluid cycle 201 and the refrigerant cycle 203 may be (e.g., thermally) connected to each other via a heat exchanger 211. The heat exchanger 211 may perform heat exchange between the refrigerant and the cooling fluid.

The cooling fluid cycle 201 may include a heater 220 configured to heat the cooling fluid and a heat exchanger 211 configured to cool the cooling fluid through heat exchange with the refrigerant. The substrate support 170, the heat exchanger 211, and the heater 220 may be connected through a flow path through which the cooling fluid flows, and a pump 240 for circulating the cooling fluid may be mounted in the flow path.

The heater 220 may include a suitable device for heating the cooling fluid flowing through the flow path. In an implementation, the heater 220 may include a resistance heater installed in the flow path through which the cooling fluid flows.

The cooling fluid cycle 201 may include a three-way valve 230 for adjusting the flow rate of the cooling fluid via the heat exchanger 211 and the flow rate of the cooling fluid via the heater 220. In an implementation, the cooler 200 may adjust the flow rate of the cooling fluid via the heat exchanger 211 and the flow rate of the cooling fluid via the heater 220 through the three-way valve 230, and therefore, the temperature of the cooling fluid to be supplied to the substrate support 170 may be adjusted. The cooler 200 may supply a mixed cooling fluid which is a mixture of the cooling fluid via the heat exchanger 211 and the cooling fluid via the heater 220, to the substrate support 170, thereby controlling the temperatures of the substrate support 170 and the substrate 300 on the substrate support 170.

In an implementation, the heat exchanger 211 and an outlet of the cooling channel 171 may be connected through the first flow path 251, and the heat exchanger 211 and an inlet of the cooling channel 171 of the substrate support 170 may be connected through the second flow path 253, and the heater 220 may be installed in a bypass flow path 255 connecting the first flow path 251 to the second flow path 253. The bypass flow path 255 may directly connect the first flow path 251 to the second flow path 253 without passing through the heat exchanger 211. The bypass flow path 255 may allow all or part of the cooling fluid to supply to the substrate support 170 without passing through the heat exchanger 211. The three-way valve 230 may be arranged at a position where the first flow path 251 and the bypass flow path 255 intersect, thereby adjusting the flow rates of the cooling fluid via the heat exchanger 211 and the cooling fluid via the heater 220. In this case, the temperature of the cooling fluid to be supplied to the substrate support 170 may be determined by the mixture of the cooling fluid via the heat exchanger 211 and the cooling fluid via the heater 220.

In an implementation, the cooler 200 may quickly increase the temperature of the cooling fluid, by reducing or completely blocking the flow rate of the cooling fluid via the heat exchanger 211 and increasing the flow rate of the cooling fluid via the heater 220, by way of controlling the three-way valve 230. In an implementation, the cooler 200 may quickly lower the temperature of the cooling fluid, by reducing or completely blocking the flow rate of the cooling fluid via the heater 220 and increasing the flow rate of the cooling fluid via the heat exchanger 211, by way of controlling the three-way valve 230.

The refrigerant cycle 203 may include a refrigerant cooler 210 and a refrigerant passage 219 through which the refrigerant circulates. The refrigerant cooler 210 may include, e.g., various devices for cooling the refrigerant flowing through the refrigerant passage 219. In an implementation, the refrigerant cooler 210 may include a condenser, a compressor, an expansion valve, and the like that constitute the refrigerant cycle 203. The heat exchanger 211 may exchange heat between the refrigerant to be supplied through the refrigerant passage 219 through which the refrigerant flows and the cooling fluid to be supplied through the first passage 251, thereby cooling the cooling fluid.

In an implementation, the temperature of the cooling fluid may be quickly controlled by adjusting the flow rate via the heat exchanger 211 and the flow rate via the heater 220 by way of the three-way valve 230, and therefore, the cooling fluid with the temperature suitable for performing the cryogenic etching process may be quickly provided to the substrate 300.

In an implementation, when the temperature of the substrate support 170 is to be increased, the temperature of the cooling fluid may be quickly increased by reducing or blocking the flow rate of the cooling fluid via the heat exchanger 211 and increasing the flow rate of the cooling fluid via the heater 220. In an implementation, for preventive maintenance (PM) with respect to the substrate processing apparatus 10, when it is necessary to raise the temperature from the cryogenic temperature to the temperature suitable for the PM, the cooling device 200 may quickly increase the temperature of the substrate support 170 by flowing most of the cooling fluid to the heater 220.

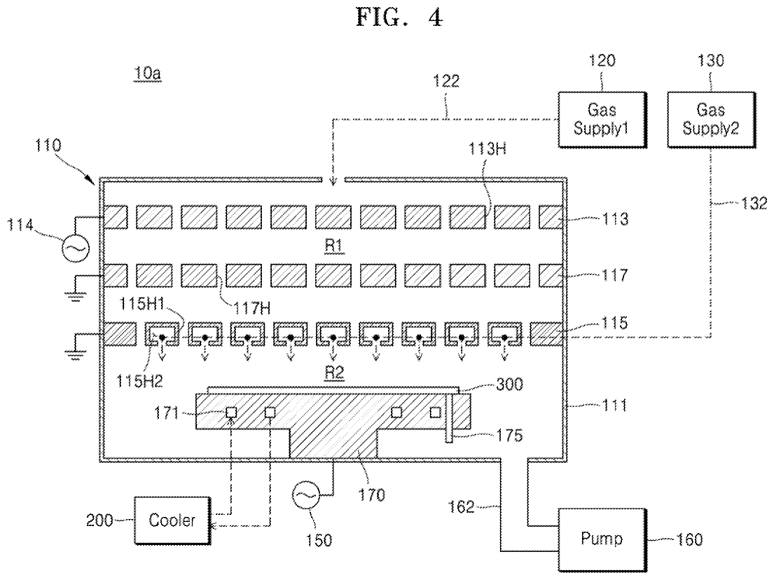

FIG. 4 is a cross-sectional view of a substrate processing apparatus 10a according to example embodiments. Hereinafter, for convenience of description, a description will be given focusing on differences from the substrate processing apparatus 10 described with reference to FIGS. 1 and 2.

Referring to FIG. 4, an RF source 114 may be connected to the first shower head 113. The RF source 114 may generate the RF power and apply the RF power to the plasma region R1 through the first shower head 113. The RF source 114 may include at least two sources to generate and output the RF power of various frequencies. In an implementation, the RF source 114 may include three sources. In an implementation, among the three sources, a first source may generate the RF power with a first frequency in the range of several MHz to several tens of MHz, and a second source may generate the RF power with a second frequency in the range of several hundred kHz to several MHz, and a third source may generate the RF power with a third frequency in the range of several tens of kHz to several hundreds of kHz. In an implementation, each of the three sources of the RF source 114 may generate the power of several hundred to tens of thousands of watts (W) and apply the power to the plasma region R1. In an implementation, the number of sources of the RF source 114 may be different.

A ground plate 117 may be arranged between the first shower head 113 and the second shower head 115 in the chamber body 111 of the process chamber 110. The ground plate 117 may have a flat plate shape, and may have a circular, elliptical, or polygonal shape in plan view. The ground plate 117 may include material resistant to plasma or may include metal, ceramic, or the like. In an implementation, the material film resistant to plasma may be coated on a surface of the ground plate 117.

In an implementation, in the plasma process, the first shower head 113 may function as an upper electrode, and the ground plate 117 arranged below the first shower head 113 may function as ground. In the plasma process, when the first process gas to be supplied from the first gas supply 120 is introduced into the plasma region R1 and the RF power from the RF source 114 is applied to the first shower head 113, the first process gas between the first shower head 113 and the ground plate 117 in the electrical ground state may be excited to generate plasma in the plasma region R1. In an implementation, for the generation of plasma, the first shower head 113 may function as the upper electrode, and the second shower head 115 in the electrical ground state may function as the ground.

The ground plate 117 may include a plurality of holes 117H. The ground plate 117 may filter components of plasma to be introduced into the plurality of holes 117H of the ground plate 117. In an implementation, in the plasma process, the electrically neutral radicals may pass through the holes 117H of the ground plate 117, and the ions may not pass through the ground plate 117. Such a filtering function of the ground plate 117 may be achieved by the geometry of the hole 117H, e.g., the aspect ratio or the taper shape of the hole 117H, and the like. In an implementation, the bias power may be applied to the ground plate 117 to block the flow of ions. In an implementation, the ground plate 117 may be in the electrical ground state.

Plasma components of the plasma region R1 may be filtered while passing through the ground plate 117 and the second shower head 115, the ratio of ions/radicals to be supplied to the processing region R2 may be adjusted by using the ground plate 117 and the second shower head 115. By appropriately adjusting the ratio of ions/radicals by using the ground plate 117 and the second shower head 115, the cleaning process or the etching process may be performed with desired characteristics.

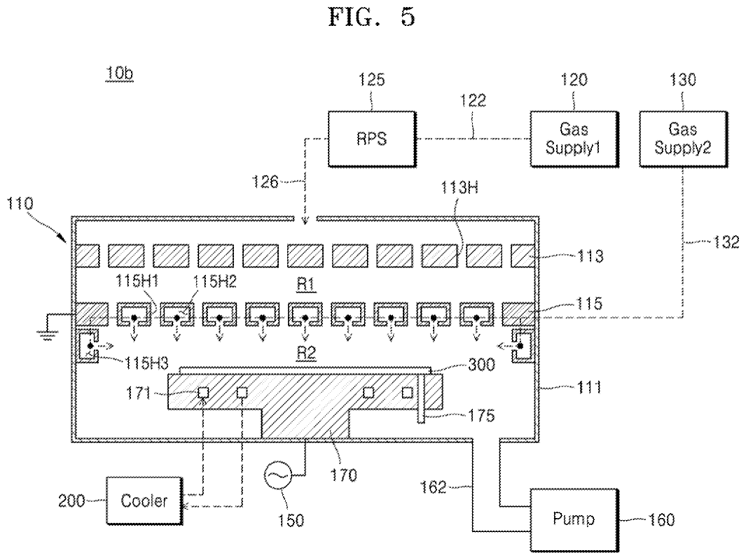

FIG. 5 is a cross-sectional view of a substrate processing apparatus 10b according to example embodiments. Hereinafter, for convenience of description, a description will be given focusing on differences from the substrate processing apparatus 10 described with reference to FIGS. 1 and 2.

Referring to FIG. 5, the second shower head 115 of the substrate processing apparatus 10b may include a third channel 115H3 configured to receive the second process gas G2 from the second gas supply 130 and to directly supply the second process gas G2 to the processing region R2. The third channel 115H3 may have a ring shape along an edge of the second shower head 115, and an outlet of the third channel 115H3 may be directed toward a center from a side of the chamber body 111, e.g., it may be formed to direct (e.g., inwardly) in the lateral direction. The third channel 115H3 may supply the second process gas G2 in the lateral direction. In an implementation, the plasma to be supplied from the plasma region R1 to the processing region R2 through the first channel 115H1 of the second shower head 115 and the second process gas G2 to be supplied from the third channel 115H3 may cross perpendicular to each other.

The third channel 115H3 of the second shower head 115 may be connected to (e.g., may be in fluid communication with) the second channel 115H2. In this case, the second shower head 115 may supply the second process gas G2 to the processing region R2 through the second channel 115H2 and the third channel 115H3. In an implementation, the third channel 115H3 of the second shower head 115 may be configured to supply the second process gas G2 to the processing region R2 independently from the second channel 115H2.

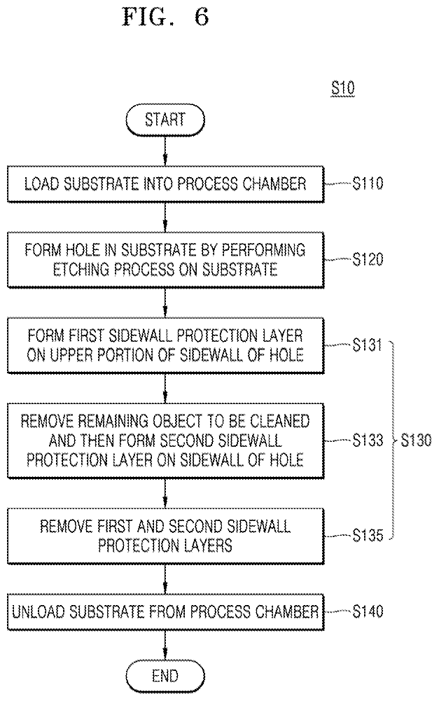

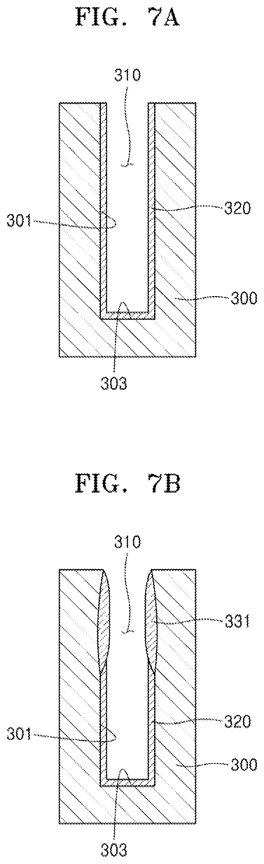

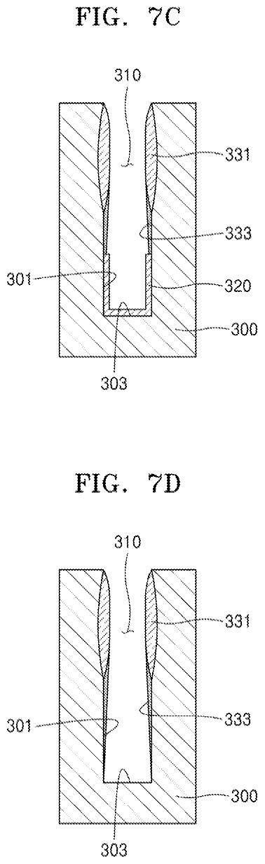

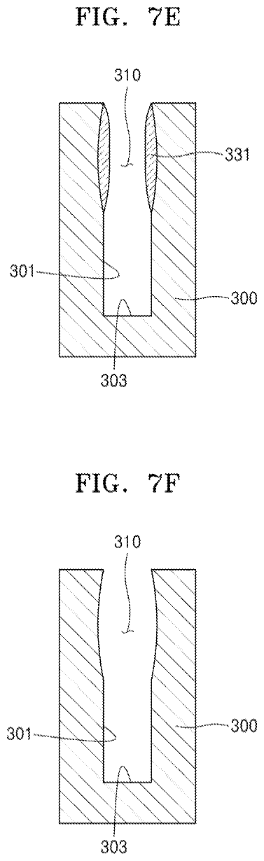

FIG. 6 is a flowchart of a substrate processing method S10 according to example embodiments. FIGS. 7A to 7F are cross-sectional views of stages in a substrate processing method according to example embodiments. Hereinafter, an example substrate processing method using the substrate processing apparatus 10 will be described with reference to FIGS. 1 to 3 together.

Referring to FIG. 6, the substrate 300 may be loaded into the process chamber 110 (S110). In an implementation, a gate provided in the chamber body 111 of the process chamber 110 may be opened, and the substrate 300 may be introduced into the process chamber 110 through the gate. The substrate 300 may be loaded (or mounted) on the substrate support 170. The substrate support 170 may support the substrate 300 by using electrostatic force.

FIGS. 6 and 7A, the etching process may be performed on the substrate 300 to form a hole 310 in the substrate 300 (S120). In an implementation, the hole 310 of the substrate 300 may have the high aspect ratio characteristic. In an implementation, a height of the hole 310 may be 30 times or more, 40 times or more, or 50 times or more than a width of the hole 310.

In an implementation, in order to form the hole 310 of the substrate 300, a mask pattern having an opening that exposes a portion of the substrate 300 may be formed on the substrate 300, and then a portion of the substrate 300 exposed through the opening of the mask pattern may be removed by using the mask pattern as an etching mask. In an implementation, a reactive ion etching process may be performed to remove the portion of the substrate 300.

In an implementation, the etching process for the substrate 300 may be a cryogenic etching process for etching the substrate at the cryogenic temperature. In order to perform the cryogenic etching process, the substrate support 170 may cool the substrate 300 such that the temperature of the substrate 300 is in the cryogenic temperature range. In an implementation, as the etching process is performed on the substrate 300, the substrate support 170 may maintain the temperature of the substrate 300 at a constant temperature of, e.g., −130° C. to −30° C. The cryogenic etching process using the plasma may help reduce the heat load applied to the substrate 300, and damage to the substrate 300 due to the plasma may be reduced. An etching profile in the cryogenic etching process using the plasma may be adjusted by the temperature of the substrate 300, and the substrate processing apparatus 10 may control the temperature of the substrate 300 at the predetermined temperature, thereby improving the reliability of the etching process with the high aspect ratio characteristics.

After the hole 310 is formed in the substrate 300, the cleaning process may be performed on the substrate 300 (S130). As the etching process is performed on the substrate 300, a material film such as a native oxide and by-products generated during the process of performing the plasma etching process may be formed on a sidewall 301 and a bottom wall 303 of the hole 310. The material film as the object to be cleaned may be selectively removed through the cleaning process. In an implementation, the cleaning process on the substrate 300 may include forming a sidewall protection layer by reacting the etchant with the object 320 to be cleaned and removing the sidewall protection layer.

Referring to FIGS. 6 and 7B, a first sidewall protection layer 331 may be formed by reacting the etchant having a reactivity with respect to the object 320 to be cleaned and a portion of the object 320 to be cleaned covering an upper portion of the sidewall 301 of the hole 310 (S131). The first sidewall protection layer 331 may be a material generated by the reaction of the etchant and the object 320 to be cleaned and may include the object 320 to be cleaned participating in the reaction. The first sidewall protection layer 331 may be generally formed first at the position close to a top end of the hole 310, and may further extend downwardly over time. As the object 320 to be cleaned covering the sidewall 301 of the hole 310 (which is located between the first sidewall protection layer 331 and the bottom wall 303 of the hole 310) is removed through a subsequent cleaning process, a portion of the substrate 300 that is covered by the first sidewall protection layer 331 may not be removed, and the first sidewall protection layer 331 may help prevent the substrate 300 from being inadvertently removed.

In an implementation, when the etchant generated by mixing NF₃ and NH₃ or the etchant generated by mixing a fluorocarbon gas and a hydrogen-nitrogen-containing gas is supplied to the substrate, the etchant may react with the object 320 to be cleaned to generate a non-volatile salt. This non-volatile salt may function as the sidewall protection layer that prevents the upper portion of the sidewall 301 of the hole 310 (e.g., a portion of the hole 310 adjacent to an opening thereof) from being etched.

In an implementation, during forming the first sidewall protection layer 331 through reaction of the etchant with the object 320 to be cleaned, the temperature of the substrate 300 may be maintained at a first temperature within the range of the cryogenic temperature. In an implementation, the first temperature of the substrate 300 may be between −130° C. to −30° C. In this case, the first temperature may be a temperature at which the first sidewall protection layer 331 may maintain the non-volatile characteristics and the first sidewall protection layer 331 may be stably adsorbed on the sidewall 301 of the hole 310. The first temperature of the substrate 300 may be provided and maintained by the cooler 200.

Referring to FIGS. 6, 7C, and 7D, the remaining object 320 to be cleaned may be removed and then a second sidewall protection layer 333 may be formed on the sidewall 301 of the hole 310 by re-deposition (S133). When the etchant reactive to the object 320 to be cleaned is supplied to the substrate 300 to remove the remaining object 320 to be cleaned, the by-products or the like may be re-deposited on the sidewall 301 of the hole 310 from which the object 320 to be cleaned is removed, thereby forming the second sidewall protection layer 333 including a polymer or the like. A material constituting the second sidewall protection layer 333 may be stably adsorbed on the sidewall 301 of the hole 310 at the cryogenic temperature. The etchant used to remove the remaining object 320 to be cleaned may be different from the etchant used when forming the first sidewall protection layer 331.

The second sidewall protection layer 333 may be generally formed first at a position close to a bottom end of the first sidewall protection layer 331, and may further extend downwardly over time (e.g., toward the bottom wall 303 of the hole 310). While the object 320 to be cleaned covering the sidewall 301 of the hole 310 (which is located between the second sidewall protection layer 333 and the bottom wall 303 of the hole 310) is removed, a portion of the substrate 300 that is covered the second sidewall protection layer 333 may not be removed, and therefore, the second sidewall protection layer 333 may help prevent the substrate 300 from being inadvertently removed.

In an implementation, while forming the second sidewall protection layer 333, the temperature of the substrate 300 may be maintained at a second temperature within the range of the cryogenic temperature. In an implementation, the second temperature of the substrate 300 may be between −130° C. to −30° C. In this case, the second temperature may be a temperature at which the first sidewall protection layer 331 and the second sidewall protection layer 333 may maintain non-volatile characteristics, and a material constituting the second sidewall protection layer 333 may be stably adsorbed on the sidewall 301 of the hole 310. In an implementation, the second temperature may be the same temperature as the first temperature or may be a different temperature. The second temperature of the substrate 300 may be provided and maintained by the cooling device 200.

Referring to FIGS. 6, 7E, and 7F, the first sidewall protection layer 331 and the second sidewall protection layer 333 in FIG. 7D may be removed (S135). As a result of the removal of the first sidewall protection layer 331 and the second sidewall protection layer 333, the sidewall 301 of the hole 310 may be exposed.

In an implementation, the substrate 300 may be heated to remove the first sidewall protection layer 331 and the second sidewall protection layer 333. The first sidewall protection layer 331 and the second sidewall protection layer 333 may be volatilized at a predetermined temperature or higher, and the first sidewall protection layer 331 and the second sidewall protection layer 333 may be removed by heating the substrate 300 to the predetermined temperature or higher. In an implementation, to remove the first sidewall protection layer 331 and the second sidewall protection layer 333, the substrate 300 may be heated to a temperature of 25° C. or higher, 50° C. or higher, or 100° C. or higher.

When the dry cleaning process for the substrate 300 is completed, the substrate 300 may be unloaded from the process chamber 110 (S140).

When a dry cleaning process is performed for a surface treatment of the hole 310 having a high aspect ratio, the upper portion of the sidewall 301 of the hole 310 could be excessively removed. However, according to example embodiments, it is possible to prevent the substrate from being inadvertently removed during the cleaning process by using the sidewall protection layer having the non-volatile characteristics in an environment of the cryogenic temperature. In an implementation, the surface of the hole having the high aspect ratio may be conformally cleaned.

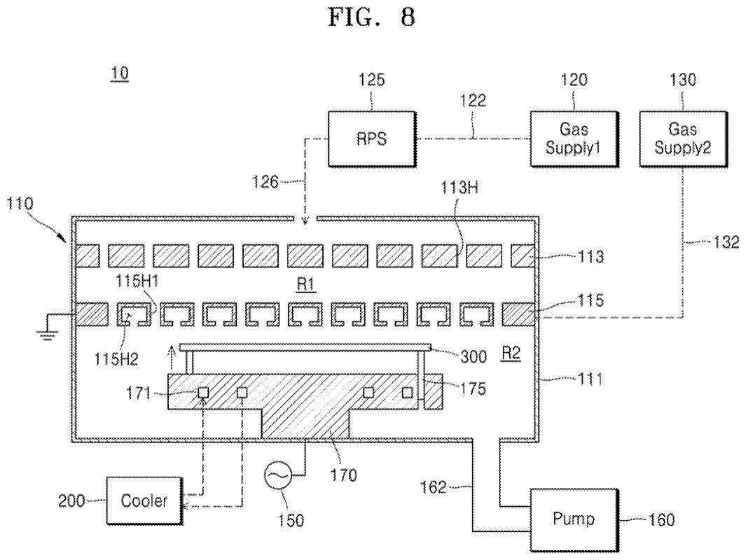

FIG. 8 is a cross-sectional view of a stage in a method of operating a substrate processing apparatus 10 according to example embodiments. Hereinafter, a method of removing the first sidewall protection layer 331 and the second sidewall protection layer 333 illustrated in FIGS. 7E and 7F will be described with reference to FIG. 8.

Referring to FIG. 8, the substrate support 170 may lift up the substrate 300 upwardly from a top surface (or a seating surface) of the substrate support 170 on which the substrate 300 may be seated by using the lift pin 175. The substrate 300 may be brought to a position close to the second shower head 115 that is maintained at a relatively high temperature (e.g., 100° C. or more) and may be separated to be relatively far from the substrate support 170 having the cryogenic temperature. The substrate 300 lifted up by the lift pin 175 may be close to the second shower head 115 with the high temperature, the substrate 300 may be heated, and as a result of the heating of the substrate 300, the first sidewall protection layer 331 and the second sidewall protection layer 333 may be removed by volatilization from an inner wall of the hole 310.

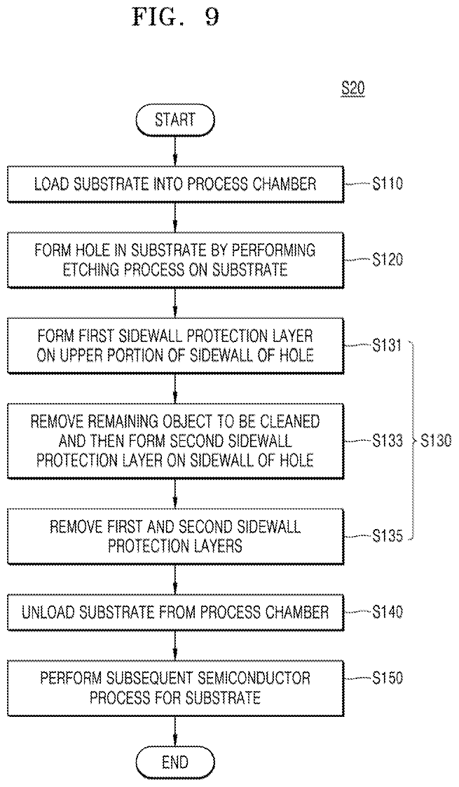

FIG. 9 is a flowchart of a method S20 of manufacturing a semiconductor device according to example embodiments.

In the method S20 of manufacturing the semiconductor device according to this example embodiment, stages S110 to S140 described with reference to FIGS. 6 and 7A to 7F may be sequentially performed. Stages S110 to S140 are the same as those described in the description of FIGS. 6 and 7A to 7F.

Thereafter, a subsequent semiconductor process for the substrate may be performed (S150). The subsequent semiconductor process may include various processes. In an implementation, the subsequent semiconductor process may include the deposition process, the etching process, the ion process, the cleaning process, or the like. Here, the deposition process may include various material layer formation process such as CVD, sputtering, and spin coating. The etching process and the cleaning process may be process using plasma or process not using plasma. The ion process may include process such as ion implantation, diffusion, and heat treatment. This subsequent semiconductor process may be performed to form integrated circuits and interconnections on the substrate, thereby manufacturing the required semiconductor device.

In an implementation, the subsequent semiconductor process may include a process of individualizing a wafer corresponding to the substrate into each semiconductor chip, and a packaging process of mounting the semiconductor chip on a printed circuit board and sealing it with a sealing material. The subsequent semiconductor processes may also include a test process for testing the semiconductor device or package. By performing these subsequent semiconductor processes, the semiconductor device or semiconductor package may be completed.

In the method of manufacturing the semiconductor device according to example embodiments, the plasma process for the substrate, e.g., the dry cleaning process or the dry etching process, may be effectively performed by using the substrate processing apparatuses 10, 10a, or 10b of FIGS. 1 to 5. Accordingly, the method of manufacturing the semiconductor device according to example embodiments may manufacture the semiconductor device with the highly reliability.

By way of summation and review, in order to improve the reliability of a product, it may be necessary to reduce the damage of a substrate caused by the plasma during the plasma process.

One or more embodiments may provide a substrate processing apparatus using plasma.

One or more embodiments may provide a substrate processing apparatus capable of effectively processing a substrate by using plasma.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A substrate processing apparatus, comprising:
a plasma region in which plasma is generated;
a processing region in which a substrate is processable;
a shower head including a first channel and a second channel, the first channel being a passage through which the plasma flows between the plasma region and the processing region and the second channel being a passage through which a process gas is supplied to the processing region, the first channel and the second channel being separated from each other;
a substrate support supporting the substrate in the processing region; and
a cooler configured to supply a cooling fluid to a cooling channel of the substrate support.

2. The substrate processing apparatus as claimed in claim 1, wherein the cooler includes:
a refrigerant cycle through which a refrigerant circulates;
a cooling fluid cycle through which the cooling fluid circulates; and
a heat exchanger configured to perform heat exchange between the refrigerant and the cooling fluid.

3. The substrate processing apparatus as claimed in claim 2, wherein the cooler further includes:
a heater configured to heat the cooling fluid; and
a three-way valve configured to adjust a flow rate of the cooling fluid via the heat exchanger and a flow rate of the cooling fluid via the heater.

4. The substrate processing apparatus as claimed in claim 1, wherein the shower head is in an electrical ground state.

5. The substrate processing apparatus as claimed in claim 1, wherein:
the plasma region and the processing region are separated by the shower head, and
in the processing region, radicals supplied through the first channel of the shower head and the process gas supplied through the second channel of the shower head are mixed to generate an etchant for processing the substrate.

6. The substrate processing apparatus as claimed in claim 1, further comprising a ground plate arranged above the shower head and including holes through which the plasma flows,
wherein the ground plate is in an electrical ground state.

7. The substrate processing apparatus as claimed in claim 1, further comprising:
a first gas supply configured to supply a first process gas; and
a remote plasma supply configured to generate the plasma from the first process gas and to supply the generated plasma to the plasma region,
wherein the process gas supplied to the shower head is a second process gas different from the first process gas.

8. The substrate processing apparatus as claimed in claim 1, wherein an RF bias power is applied to the substrate support.

9. The substrate processing apparatus as claimed in claim 1, wherein the substrate support includes a lift pin configured to move the substrate in a vertical direction.

10. The substrate processing apparatus as claimed in claim 1, wherein the shower head further includes a third channel configured to supply a process gas to the processing region in a lateral direction, the third channel being connected to the second channel.

11. A substrate processing apparatus, comprising:
a plasma region to which plasma generated from a first process gas is supplied;
a processing region in which the plasma supplied from the plasma region and a second process gas are mixed to generate an etchant for processing a substrate;
a substrate support on which the substrate is supportable in the processing region; and
a cooler configured to supply a cooling fluid to a cooling channel of the substrate support,
wherein the cooler includes:
a refrigerant cycle through which a refrigerant circulates;
a cooling fluid cycle through which the cooling fluid circulates; and
a heat exchanger configured to perform heat exchange between the refrigerant and the cooling fluid.

12. The substrate processing apparatus as claimed in claim 11, wherein the cooling fluid cycle includes:
a first flow path extending between an outlet of a cooling channel of the substrate support and an inlet of the heat exchanger;
a second flow path extending between an outlet of the heat exchanger and an inlet of the cooling channel;
a bypass flow path connecting the first flow path to the second flow path without passing through the heat exchanger; and
a heater installed in the bypass path and configured to heat the cooling fluid.

13. The substrate processing apparatus as claimed in claim 12, wherein the cooler is configured to adjust a temperature of the cooling fluid by adjusting a flow rate of the cooling fluid through the heat exchanger and a flow rate of the cooling fluid through the heater.

14. The substrate processing apparatus as claimed in claim 11, further comprising a shower head separating the plasma region from the processing region,
wherein the shower head includes a first channel, which is a passage through which the plasma in the plasma region is supplied to the processing region, and a second channel, which is a passage through which the second process gas is supplied to the processing region.

15. The substrate processing apparatus as claimed in claim 14, wherein the first channel and the second channel of the shower head are separated from each other.

16. The substrate processing apparatus as claimed in claim 14, further comprising:
a remote plasma supply configured to supply the plasma generated from the first process gas to the plasma region;
a first gas supply configured to supply the first process gas to the remote plasma supply; and
a second gas supply configured to supply the second process gas to the shower head.

17. The substrate processing apparatus as claimed in claim 14, wherein the shower head further includes a third channel configured to supply the second process gas to the processing region in a lateral direction, the third channel being connected to the second channel.

18. The substrate processing apparatus as claimed in claim 14, wherein:
the substrate support includes a lift pin configured to lift up the substrate toward the shower head,
the shower head is maintained at a second temperature higher than the first temperature, and
after the substrate is processed at a first temperature by using the etchant, the substrate processing apparatus is configured to lift up the substrate toward the shower head that is at the second temperature to heat the substrate.

19. The substrate processing apparatus as claimed in claim 11, further comprising:
an upper electrode configured to receive RF power; and
a ground plate spaced apart from the upper electrode with the plasma region therebetween and being in an electrical ground state.

20. A substrate processing apparatus, comprising:
a process chamber including a plasma region, a processing region, a shower head separating the plasma region from the processing region, and a substrate support on which a substrate is supportable in the processing region;
a remote plasma supply configured to generate a plasma from a first process gas and to supply the plasma to the plasma region;
a first gas supply configured to supply the first process gas to the remote plasma supply;
a second gas supply configured to supply a second process gas to the shower head; and
a cooler configured to cool the substrate support, the cooler including a refrigerant cycle through which a refrigerant circulates, a cooling fluid cycle through which a cooling fluid circulates, and a heat exchanger performing heat exchange between the refrigerant and the cooling fluid,
wherein:
the shower head includes a first channel configured to supply the plasma in the plasma region to the processing region and a second channel configured to supply the second process gas to the processing region, and
the first channel and the second channel are separated from each other, and radicals to be supplied to the processing region through the first channel and the second process gas supplied through the second channel are mixed to generate an etchant for cleaning the substrate.

21-25. (canceled)
